(19) United States
(12) Patent Application Publication
(10) Pub. No.: US 2008/0128853 A1
(43) Pub. Date: Jun. 5, 2008

(54) Non-Volatile Memory Devices with Discrete Resistive Memory Material Regions and Methods of Fabricating the Same

(75) Inventors: Suk-hun Choi, Gyeonggi-do (KR); In-gyu Baek, Seoul (KR); Jun-young Lee, Gyeonggi-do (KR); Jung-hyeon Kim, Gyeonggi-do (KR); Chang-ki Hong, Gyeonggi-do (KR); Yoon-ho Son, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/939,041

(22) Filed: Nov. 13, 2007

(30) Foreign Application Priority Data
Nov. 13, 2006 (KR) 2006-111879

(51) Int. Cl. H01L 29/00; H01L 21/02

(52) U.S. Cl. 257/530; 438/104; 257/E21.006; 257/E29.001

(57) ABSTRACT

A semiconductor memory device includes a first conductive line on a semiconductor substrate, an interlayer insulating layer on the first conductive line, a second conductive line on the interlayer insulating layer, and a memory cell in an hole through the interlayer insulating layer wherein the first and second conductive lines cross, the memory cell including a discrete resistive memory material region disposed in the hole and electrically connected between the first and second conductive lines. The resistive memory material region may be substantially contained within the hole. In some embodiments, contact between the resistive memory material region and the interlayer insulating layer is substantially limited to sidewalls of the interlayer insulating layer in the hole.

### REFERENCE TO PRIORITY APPLICATIONS

This claims the benefit of Korean Patent Application No. 10-2006-0111879, filed on Nov. 13, 2006, the disclosure of which is hereby incorporated herein by reference in its entirety.

### FIELD OF THE INVENTION

The present invention relates to a memory devices and methods of fabricating the same and, more particularly, to resistive non-volatile memory devices methods of fabricating the same.

### BACKGROUND OF THE INVENTION

The use of non-volatile memory devices in portable digital appliances, such as digital cameras, mp3 players, personal digital assistants (PDA), and cellular phones has rapidly expanded. Flash memory devices are widely used for such applications. A typical flash memory device cell comprises single floating gate MOS transistors, which may provide a highly integrated memory device at low cost. However, as further reduction of manufacturing costs and higher integration of memory devices is desired, development continues on new memory devices that may overcome the limits of conventional flash memory devices.

For example, memory devices have been developed having a memory cell structure using a resistive memory material. A typical resistive memory material has at least two stable resistive states, which may be reversibly switched by applying electric pulses to the resistive memory material. Thus, the resistive memory material may find application in non-volatile memory devices.

Examples of resistive memory materials include colossal magneto-resistive (CRM) materials having a Perovskite structure and high-temperature super-conducting (HTSC) materials. However, these materials usually include four or more components and may thus be difficult to manufacture. Compatibility of these materials with existing silicon processes may also be problematic. To overcome such problems, a two-component transition metal oxide, for example, nickel oxide (NiO) or niobium oxide (NbO), has been suggested as a candidate resistive memory material.

FIG. 1A is a perspective view illustrating a conventional non-volatile memory device having resistive memory cells 40, while FIG. 1B is a cross-sectional view of FIG. 1A along a line IB. The conventional non-volatile memory device includes a resistive memory cell 40 that is electrically connected via a conductive plug 30 to a word line 21 formed on a semiconductor substrate 10. The resistive memory cell 40 may include metal bottom and top electrodes 41, 43 and a resistive memory material layer 42 interposed between the bottom electrode 41 and the top electrode 43. The top electrode 43 is electrically connected to a bit line 22 extending transverse to the word line 21. Thus, the memory device has an array structure in which respective portions of the resistive structures 40 are disposed at respective crossing points between the word lines 21 and the bit lines 22 is formed. Such a device may be referred to as a cross point non-volatile memory device.

If a nickel-containing material is used as a resistive memory material in a cross-point memory device such as that shown in FIG. 1A, a nickel silicide layer a may be formed at an interface between the resistive memory material layer 42 and the interlayer insulating layer 50, as shown in FIG. 1B. If the resistive memory material layer 42 is formed by plasma etching, etching damage may occur at sidewalls of the resistive memory material layer 42, which may generate device defects.

FIG. 2 is a SEM image showing a cross-section of the resistive structure such as that illustrated in FIGS. 1A and 1B. Referring to FIG. 2, a nickel silicide layer formed at the interface between the resistive memory material layer and the interlayer insulating layer has bubble defects. This may reduce a bond strength between the resistive memory material layer 42 and the interlayer insulating layer 50, and thus may cause a lift-off phenomenon in which the resistive memory material layer 42 is separated from the interlayer insulating layer 50, as illustrated at locations b in FIG. 1B,

A cross point non-volatile memory device with shared bit lines may be formed by forming another resistive memory cell array structure on a bit line such as that shown in FIGS. 1A and 1B in order to increase the memory cell density. In forming such a device, a high-temperature process may be used to form the top memory cell array. Bubble defects and lift-off due to silicide formation may be an impediment to producing reliable non-volatile memory devices with such a structure.

### SUMMARY OF THE INVENTION

In some embodiments of the present invention, a semiconductor memory device includes a first conductive line on a semiconductor substrate, an interlayer insulating layer on the first conductive line, a second conductive line on the interlayer insulating layer, and a memory cell at an intersection of the first and second conductive lines. The memory cell includes a discrete resistive memory material region disposed in a hole through the interlayer insulating layer and electrically connected between the first and second conductive lines. The resistive memory material region may be substantially contained within the hole. In some embodiments, contact between the resistive memory material region and the interlayer insulating layer is substantially limited to sidewalls of the interlayer insulating layer in the hole.

The memory cell may include a conductive region and/or a diode in the hole and electrically connected between the resistive memory material region and the first conductive line. In some embodiments, an electrode may be disposed on the interlayer insulating layer and may connect the resistive memory material region to the second conductive line. In other embodiments, the memory cell may include an electrode disposed in a recess defined by the resistive memory material region and in contact with the second conductive line. The first conductive line may be a word line and the second conductive line may be a bit line.

In further embodiments, a second interlayer insulating layer is disposed on the second conductive line and a third conductive line is disposed on the second interlayer insulating layer. A second memory cell is disposed at an intersection of the second and third conductive lines. The second memory cell includes a discrete resistive memory material region disposed in a hole through the second interlayer insulating layer and electrically connected between the second and third conductive lines. The second memory cell may have a structure similar to the first memory cell.

In method embodiments of the present invention, a first conductive line is formed on a substrate. An interlayer insulating layer is formed on the conductive line. A portion of the interlayer insulating layer is removed to form a hole that exposes the first conductive line. A memory cell is formed on the exposed first conductive line, the memory cell including a discrete resistive memory material region in the hole and in contact with first conductive line. A second conductive line is formed on the interlayer insulating layer and the memory cell, the second conductive line electrically connected to the resistive memory material region.

Forming a memory cell may include forming a first conductive material layer on the interlayer insulating layer and in the hole, planarizing the first conductive material layer to expose the interlayer insulating layer and leave a portion of the first conductive material layer in the hole, etching a portion of the conductive material layer remaining in the hole to form a recessed conductive plug in the hole and forming the resistive memory material region on the recessed conductive plug. In some embodiments, forming a memory cell further includes forming a second conductive layer on the first interlayer insulating layer and on the conductive plug in the hole, planarizing the second conductive layer to expose the interlayer insulating layer and leave a portion of the second conductive layer in the hole, etching a portion of the second conductive layer remaining in the hole to leave a recessed electrode in the hole and on the conductive plug, and forming the resistive memory material region on the electrode.

In some embodiments, forming a memory cell includes forming a semiconductor material layer on the interlayer insulating layer and in the hole, planarizing the semiconductor material layer to expose the interlayer insulating layer and leave a portion of the semiconductor material layer in the hole, etching a portion of the semiconductor material remaining in the hole to form a recessed semiconductor region in the hole, implanting impurities into the semiconductor region to form a diode and forming the resistive memory material region on the diode. Forming a memory cell may further include forming a conductive layer on the first interlayer insulating layer and on the diode in the hole, planarizing the conductive layer to expose the interlayer insulating layer and leave a portion of the conductive layer in the hole, etching a portion of the conductive layer remaining in the hole to leave a recessed electrode on the diode and forming the resistive memory material region on the electrode.

In additional embodiments, forming a memory cell includes forming an electrode in the hole in electrical contact with the first conductive line, forming a resistive memory material layer on the interlayer insulating layer and on the electrode in the hole and planarizing the resistive memory material layer to expose the interlayer insulating layer and leave the resistive memory material region on the electrode in the hole. In some embodiments, forming a resistive memory material layer on the interlayer insulating layer and on the electrode in the hole includes forming the resistive memory material layer on the electrode to a thickness sufficient to fully fill the hole and planarizing the resistive memory material layer to expose the interlayer insulating layer and leave the resistive memory material region on the electrode in the hole includes planarizing the resistive memory material layer such that the resistive memory material region on the electrode in the hole is substantially flush with the exposed interlayer insulating layer. Forming a memory cell may further include forming a second electrode on the interlayer insulating layer and the resistive memory material region and forming a second conductive line may include forming the second conductive line on the second electrode.

In further embodiments, forming a resistive memory material layer on the interlayer insulating layer and on the electrode in the hole includes forming the resistive memory material layer to a thickness sufficient to cover a bottom and sidewall of the hole and define a recess bounded by the resistive memory material layer. Planarizing the resistive memory material layer to expose the interlayer insulating layer and leave the resistive memory material region on the electrode in the hole may be proceeded by forming a conductive material layer on the resistive memory material layer, and may further include planarizing the conductive material layer and the resistive memory material layer such that a second electrode is formed in the recess in the resistive memory material region. Forming a second conductive line may include forming the second conductive line on the second electrode.

In still further embodiments, a second interlayer insulating layer is formed on the second conductive line. A portion of the second interlayer insulating layer is removed to form a hole through the second interlayer insulating layer that exposes the second conductive line. A second memory cell is formed on the exposed first conductive line, the second memory cell including a discrete resistive memory material region in the hole through the second interlayer insulating layer and in contact with the second conductive line. A third conductive line is formed on the second interlayer insulating layer and the second memory cell, the third conductive line electrically connected to the resistive memory material region of the second memory cell.

### BRIEF DESCRIPTION OF THE DRAWINGS

The above and other features and advantages of the present invention will become more apparent by describing in detail exemplary embodiments thereof with reference to the attached drawings in which:

FIG. 1A is a perspective view illustrating a conventional cross-point non-volatile memory device;

FIG. 1B is a cross-sectional view of FIG. 1A;

FIG. 2 is an SEM image showing a cross-section of a device having the structure illustrated in FIGS. 1A and 1B;

FIGS. 3-6 are perspective views illustrating resistive semiconductor memory devices according to some embodiments of the present invention;

FIGS. 7-10 are cross-sectional views of the devices of FIGS. 3-6, respectively;

FIGS. 11-22 are cross-sectional views of fabrication products illustrating operations for fabricating semiconductor memory devices according to some embodiments of the present invention;

FIGS. 23-26 are perspective views illustrating laminated resistive semiconductor memory devices according to further embodiments of the present invention; and

FIGS. 27-30 are cross-sectional views of the devices of FIGS. 23-26, respectively.

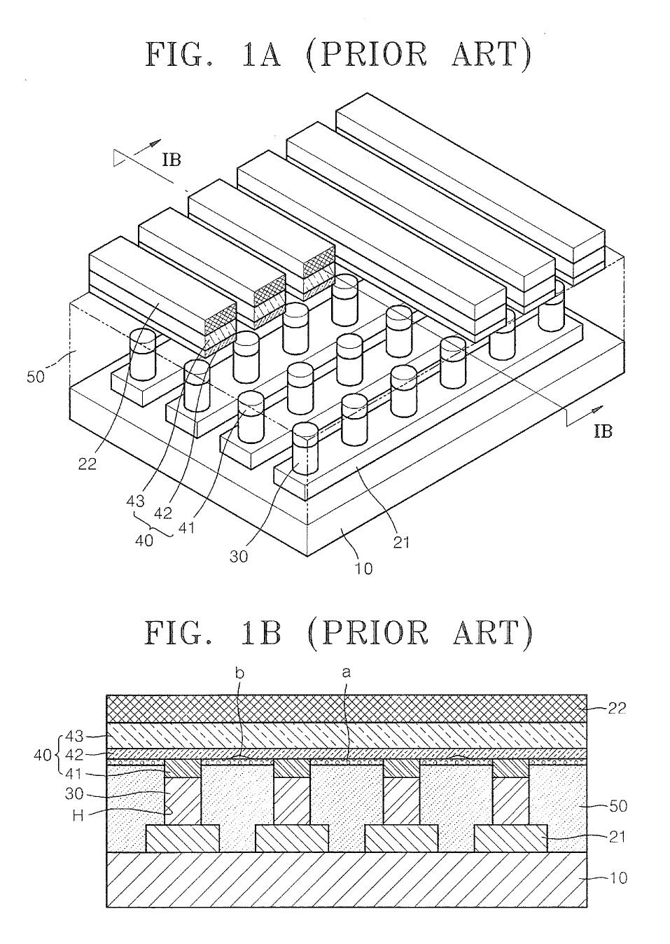

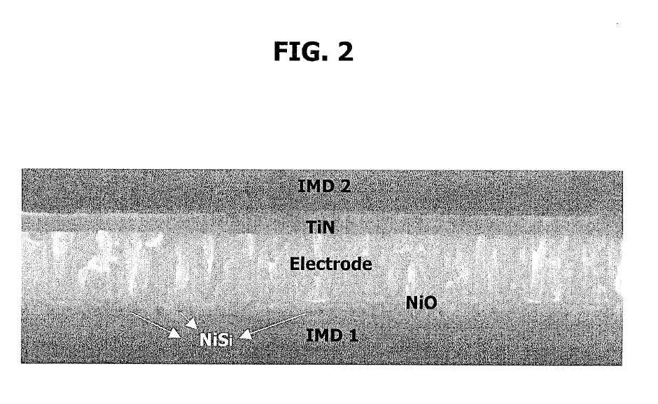

### DETAILED DESCRIPTION OF EMBODIMENTS

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that when an element or layer is referred to as being “on,” “connected to” and/or “coupled to” another element or layer, the element or layer may be directly on, connected and/or coupled to the other element or layer, or intervening elements or layers may be present. In contrast, when an element is referred to as being “directly on,” “directly connected to” and/or “directly coupled to” another element or layer, no intervening elements or layers are present. As used herein, the term “and/or” includes any and all combinations of one or more of the associated listed items.

It will also be understood that, although the terms “first,” “second,” etc., may be used herein to describe various elements, components, regions, layers and/or sections, these elements, components, regions, layers and/or sections should not be limited by these terms. Rather, these terms are used merely as a convenience to distinguish one element, component, region, layer and/or section from another element, component, region, layer and/or section. For example, a first element, component, region, layer and/or section could be termed a second element, component, region, layer and/or section without departing from the teachings of the present invention.

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly. As used herein, “height” refers to a direction that is generally orthogonal to the faces of a substrate.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “comprise,” “comprising,” “includes,” “including,” “have”, “having” and variants thereof specify the presence of stated features, integers, steps, operations, elements, and/or components, but do not preclude the presence and/or addition of one or more other features, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention. Like reference numerals refer to like elements throughout.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

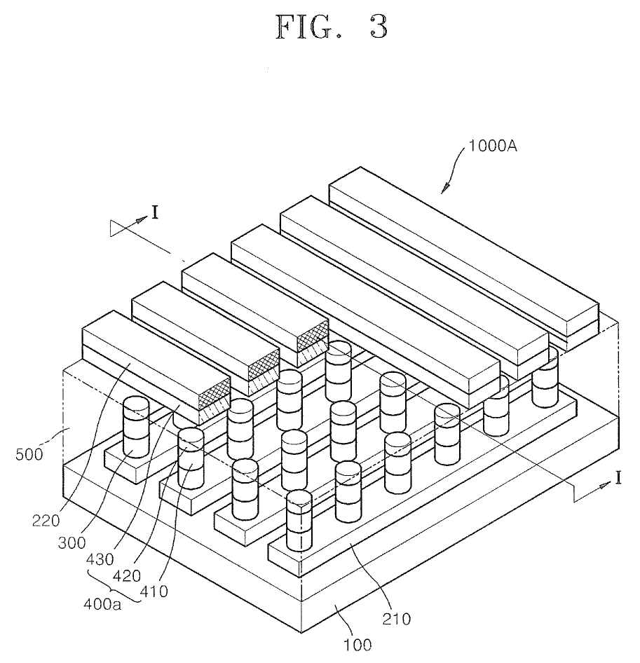

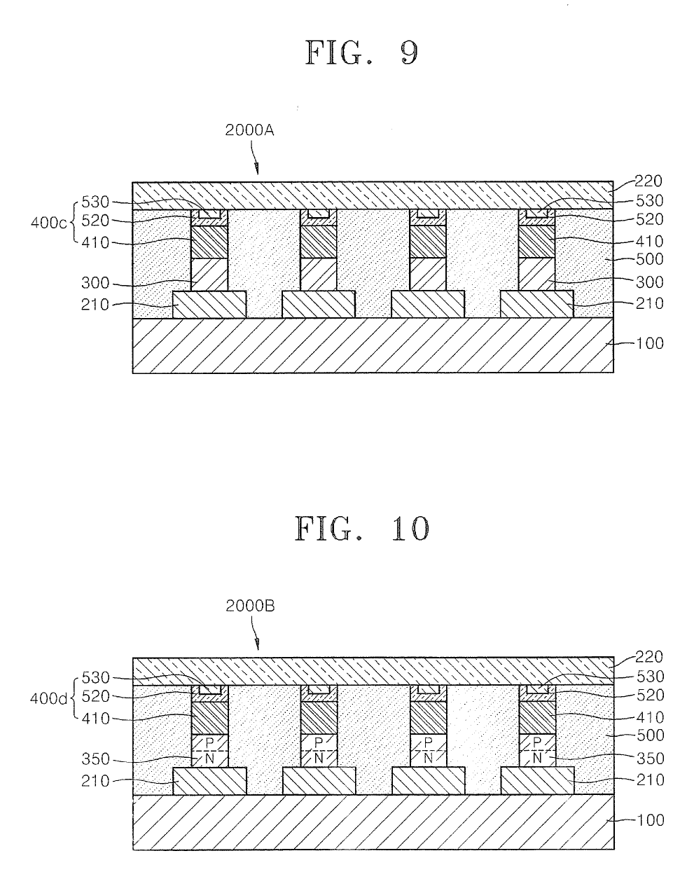

FIGS. 3-6 are perspective views illustrating semiconductor memory devices 1000A, 1000B, 2000A and 2000B, respectively, according to various embodiments of the present invention. The memory devices 1000A, 1000B, 2000A and 2000B include respective resistive memory cell structures 400a, 400b, 400c and 400d. FIGS. 7-10 are cross-sectional views of the devices of FIGS. 3-6, respectively, along lines I-IV, respectively. The memory cell structures 400a and 400b in the devices 1000A and 1000B each include a bottom electrode 410, a resistive memory material region 420, and a top electrode 430.

Referring to FIGS. 3, 4, 7 and 8, the semiconductor memory devices 1000A and 1000B each include a conductive line 210 on a semiconductor substrate 100 and an interlayer insulating layer 500 on the conductive line 210. The conductive line 210 may be used as a word line of the semiconductor memory device. The conductive line 210 may be formed, for example, of metallic materials, such as aluminum (Al) or tungsten (W). After forming the conductive line 210, an interlayer insulating layer 500 may be formed on the conductive line 210. A hole is formed in the insulating layer 500 using, for example, plasma etching to expose an upper surface of the conductive line 210.

In some embodiments of the present invention illustrated in FIGS. 3 and 7, semiconductor memory device 1000A includes a conductive plug 300 in contact with the conductive line 210. Referring to FIG. 11, to form the conductive plug 300, a conductive material layer, such as polysilicon, may be deposited on the interlayer insulating layer 500 and into a hole 500h therein. Using, for example, a chemical mechanical polishing (CMP) process or an etch-back process, planarization is performed until the upper surface of the interlayer insulating layer 500 is exposed. The conductive material layer remaining in the hole 500h may recessed, for example, using a plasma etching process to form the conductive plug 300.

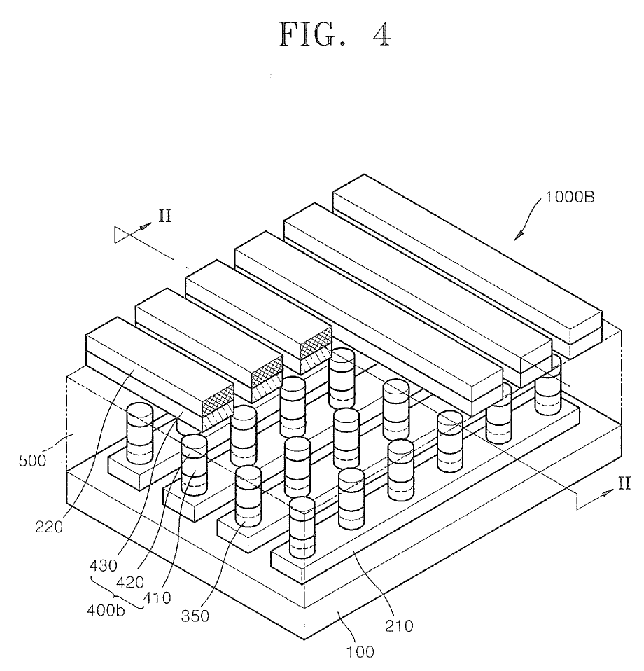

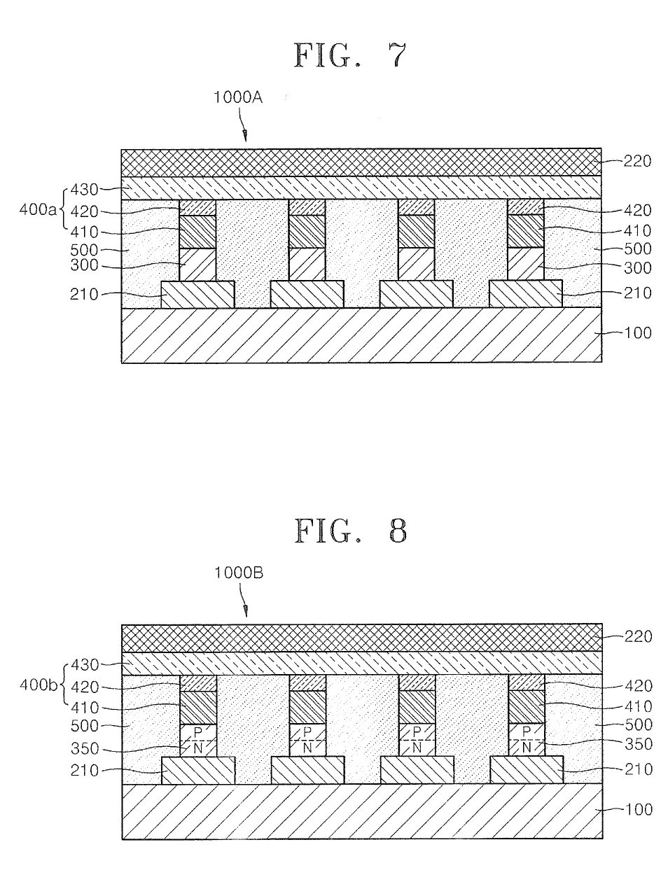

In other embodiments of the present invention illustrated in FIGS. 4 and 8, the semiconductor memory device 1000B includes a diode 350 in contact with the conductive line 210. In a cross point non-volatile memory device, when programming is performed at a selected cross point and a resistive structure at a non selected cross point neighboring the selected cross point has low electrical resistance, a portion of current for programming the selected cross point may leak out through the non selected cross point. When the current leaks out through the neighboring non selected cross points, programming current d through the resistive structure of the selected cross point may be insufficient and, thus, the programming of the selected cross point may fail. In some embodiments of the present invention illustrated in FIGS. 4 and 8, the diode 350 may be serially connected between the bottom electrode 410 and the conductive line 210 to reduce or prevent such leakage.

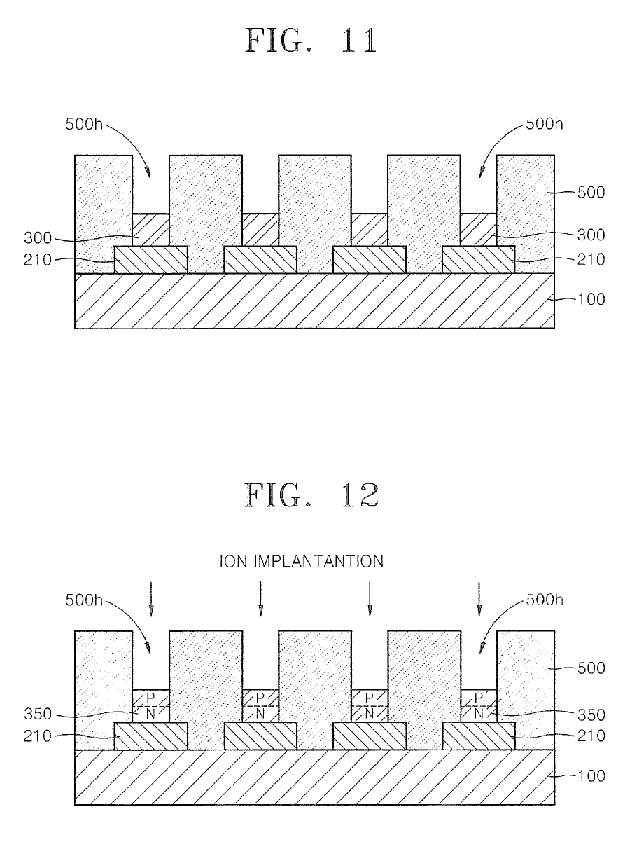

The diode 350 may formed using a process similar to that described for forming the conductive plug 300. Referring to FIG. 12, a semiconductor material layer, such as a polysilicon layer, is formed, planarized and recessed to form a semiconductor material region in the bottom of a hole 500h in the interlayer insulating layer 500. Then, n-type and/or p-type impurities may be implanted into the semiconductor material to form the diode 350. A heating process may be further performed to activate the impurity ions.

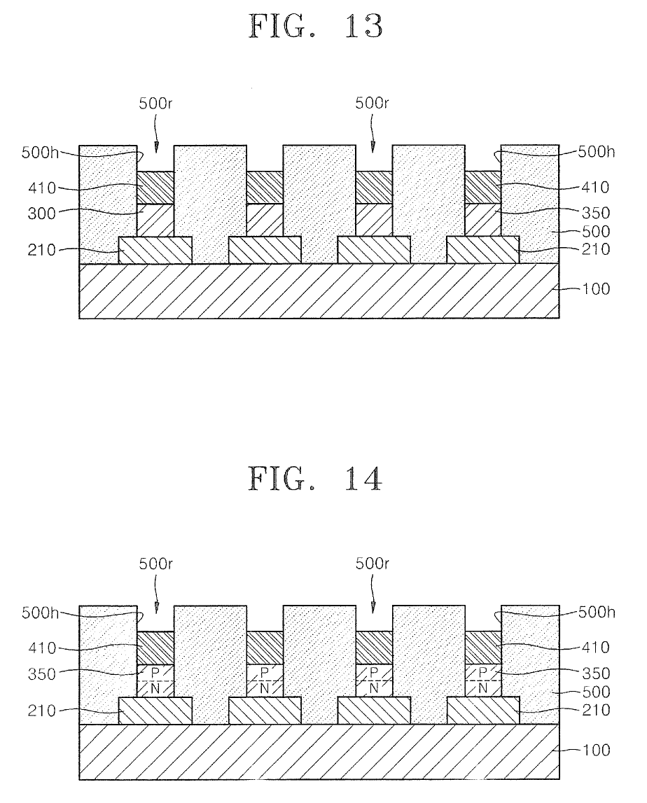

Referring to FIGS. 3, 4, 7 and 8, the semiconductor memory devices 1000A and 1000B may include bottom electrodes 410 on a first conductive plug 300 or a first diode 350. Referring to FIGS. 13 and 14, after the conductive plug 300 or the diode 350 is formed, a bottom electrode 410 may be formed on the conductive plug 300 or the diode 350. For example, a conductive layer may be deposited on the interlayer insulating layer 500 and into the hole 500h therein, and the conductive layer planarized to expose the upper surface of the interlayer insulating layer 500. Then, the conductive layer may be etched to a predetermined depth to define a recess 500r.

In some embodiments of the present invention, the bottom electrodes 410 may be formed of a noble metal, such as iridium (Ir), platinum (Pt), and ruthenium (Ru), or a combination thereof. In other embodiments of the present invention, the bottom electrode 410 may be formed of polysilicon, tungsten (W), titanium nitride (TiN), and titanium aluminum nitride (TiAlN), or a combination thereof. Tungsten has excellent characteristics as a material for a bottom electrode. Below resistive memory material regions 420 and 520 and upper electrodes 430 and 530, according to various embodiments of the present invention, will be explained by referring to FIGS. 5, 6, 9 and 10, as well as FIGS. 3, 4, 7 and 8.

The semiconductor memory devices 1000A and 1000B each include a resistive memory material region 420 formed in a hole in an interlayer insulating layer 500 on top of a bottom electrode 410 and having an upper surface substantially flush with the interlayer insulating layer 500. The memory devices 2000A and 2000B include a resistive memory material region 520 having a recess in a top surface thereof in which a top electrode 530 is formed.

The resistive memory material region 420 or 520 may be formed of a two-component metal oxide having two stable resistance states, such as oxides of nickel (Ni), niobium (Nb), titanium (Ti), zirconium (Zr), hafnium (Hf), cobalt (Co), iron (Fe), copper (Cu), and aluminum (Al), or a combination thereof. The two-component metal oxide may have a high resistance value in an initial state, which may reduce interference between neighboring cells.

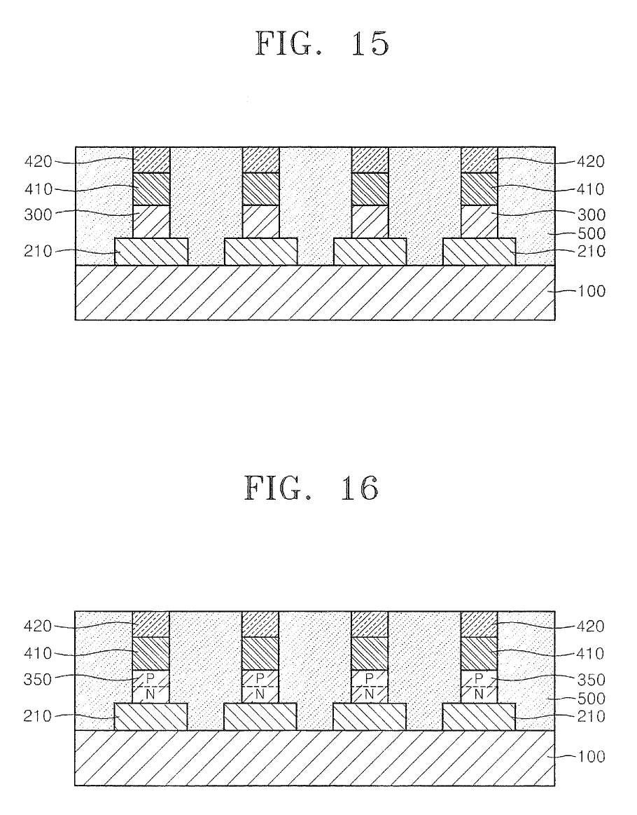

Referring to FIGS. 15 and 16, for the memory devices 1000A and 1000B, in order to form the resistive memory material region 420, a resistive memory material layer may be deposited on the interlayer insulating layer 500 to fill the recess 500r. The resistive memory material layer may be planarized until the upper surface of the interlayer insulating layer 500 is exposed to leave the resistive memory material region 420 in the recess 500r, with an upper surface at the same level as (substantially flush with) the upper surface of the interlayer insulating layer 500.

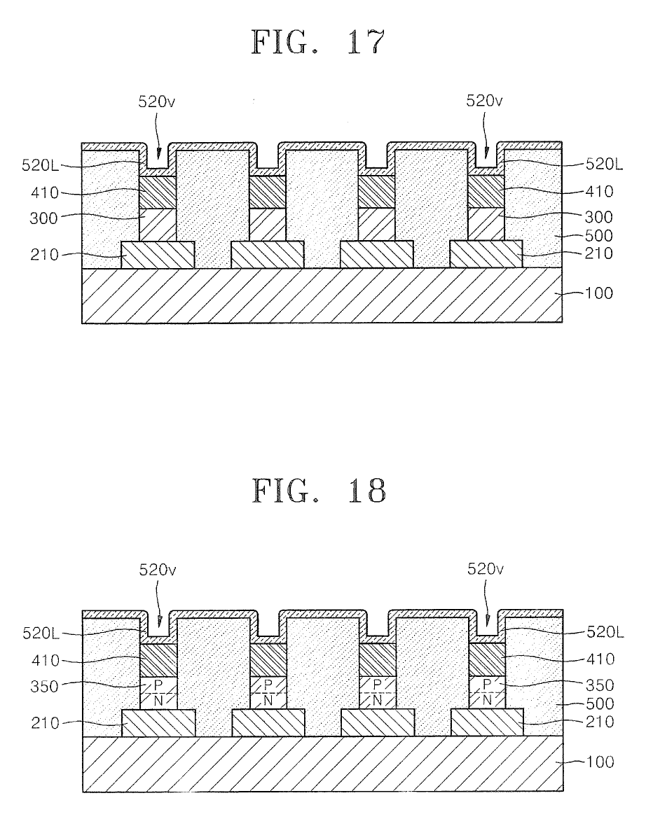

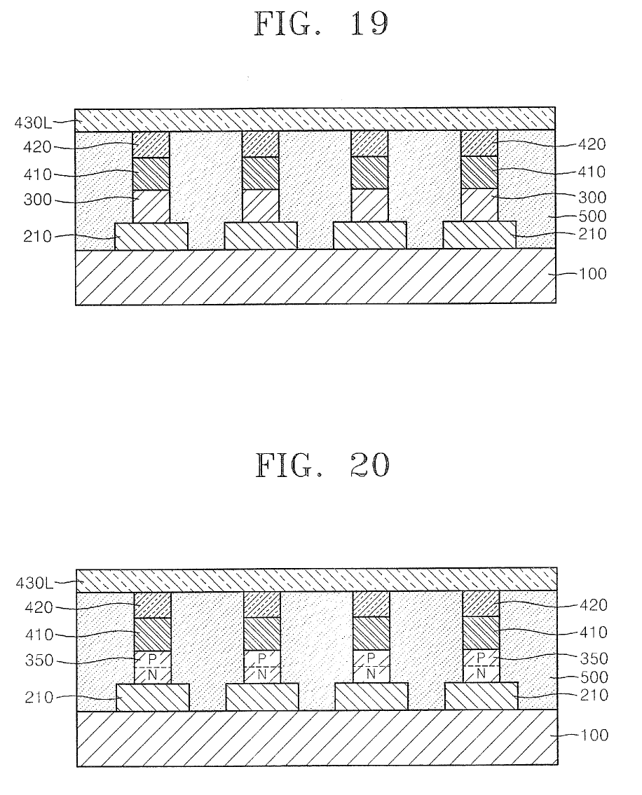

Referring to FIGS. 17 and 18, for the memory devices 2000A and 2000B, a resistive memory material layer 520L may be deposited to a predetermined thickness on the bottom and sidewalls of the recess 500r and on the interlayer insulating layer 500, defining a recess 520v in which a top electrode may be formed, as explained below.

According to some embodiments of the present invention, the resistive memory material regions 420 and 520 of the memory devices 1000A, 1000B, 2000A and 2000B are locally formed and substantially contained in a hole 500h in an interlayer insulating layer 500. Accordingly, the surface area of the interface between the resistive memory material region 420 and 520 and the interlayer insulating layer 500 may be reduced in comparison to conventional devices. This may reduce or prevent the formation of a silicide layer at the interface. Also, because the resistive memory material region 420 and 520 may be formed using a planarizing process, damage to sidewalls of the resistive memory material region 420 and 520 may be reduced or eliminated. Thus, a more reliable memory cell structure may be provided.

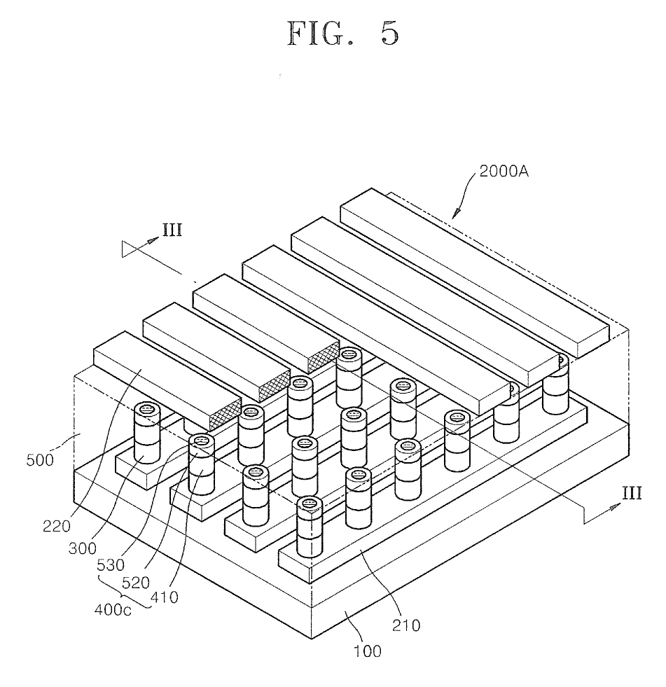

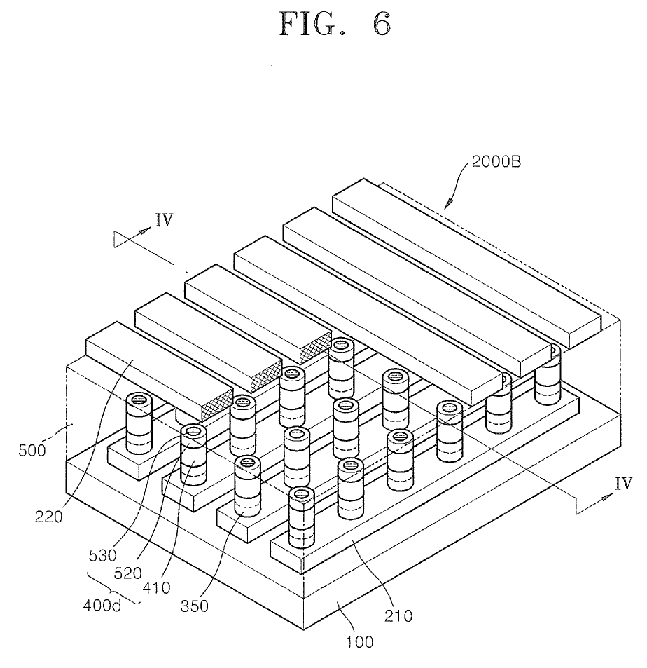

Again referring to FIGS. 3 and 4, the semiconductor memory devices 1000A and 1000B may include top electrodes 430 on resistive memory material regions 420. In some embodiments of the present invention, the top electrode 430 may be formed on the resistive memory material region 420 and the interlayer insulating layer 500 as illustrated in FIGS. 3 and 4. In other embodiments of the present invention, the semiconductor memory devices 2000A and 2000B include a top electrode 530 formed in a recess in a resistive memory material region 520, as illustrated in FIGS. 5 and 6.

Referring to FIGS. 19 and 20, to form a top electrode 430 as illustrated in FIGS. 3 and 4, a conductive material layer 530L may be deposited on the planarized resistive memory material layer 520 and on the interlayer insulating layer 500. The conductive material layer 430L may be patterned with a conductive line 220 during subsequent formation of the conductive line 220, as described below.

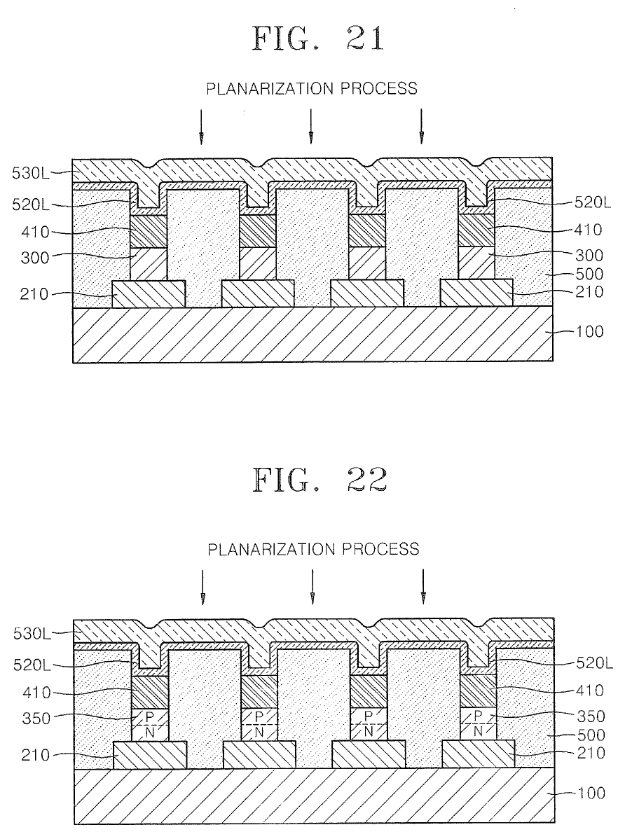

Referring to FIGS. 21 and 22, to form a top electrode 530 and resistive memory material region 520 as illustrated in FIGS. 5 and 6, a conductive material layer 530L may be deposited on the resistive memory material layer 520L to fill the recess 520v. The conductive material layer 530L and the resistive memory material layer 520L may be planarized to expose the upper surface of the interlayer insulating layer 500 and leave a top electrode 530 in the recess 520v.

The top electrode 430 and 530 may be formed from a noble metal, such as iridium (Ir), platinum (Pt), ruthenium (Ru), or a combination thereof. In some embodiments, the top electrode 530 may be formed from polysilicon, tungsten (W), titanium nitride (TiN) layer, a titanium aluminum nitride (TiAlN) layer, or a combination thereof. According to various embodiments of the present invention, when the top electrode 530 is buried in a recess 520v, lift-off of the resistive memory material region 520 from the bottom electrode 410 may be suppressed. Therefore, a noble metal, such as Ir, which is sensitive to stress but has excellent electric characteristics, may be used as a material for forming the top electrode 530.

After the top electrodes 430 or 530 are formed, a conductive line 220 that may have a linear shape and be electrically connected to the top electrode 430 or 530 may be formed. The conductive line 220 may be formed, for example, by forming an Al, W or TiN layer on the interlayer insulating layer 500 and patterning the layer. For the devices 1000A and 1000B of FIGS. 3 and 4, the conductive line 220 may be used as an etching mask to pattern the top electrode layer (430L in FIGS. 19 and 20). Alternatively, the top electrode 430 and the second conductive line 220 may be simultaneously patterned using, for example, a plasma etching process.

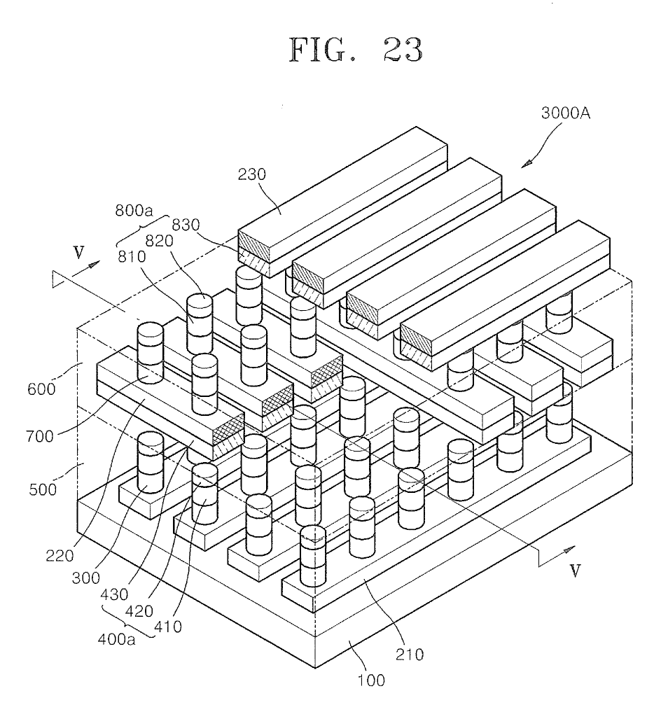

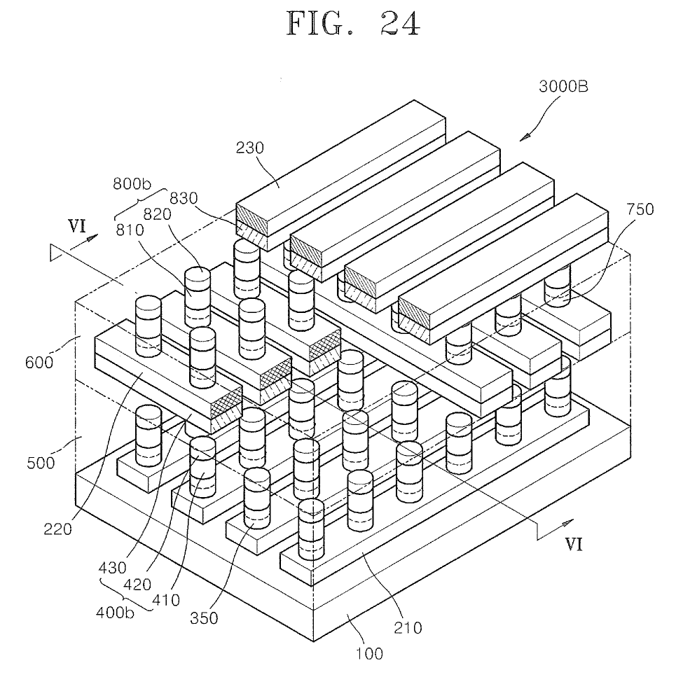

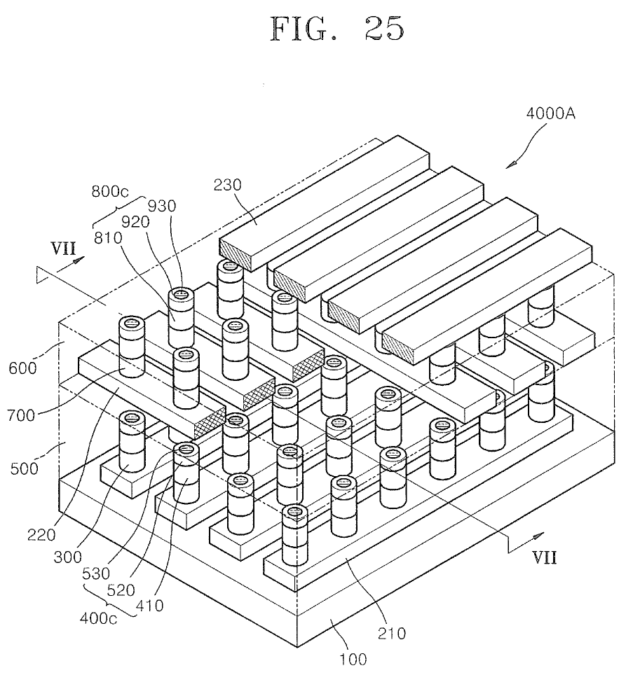

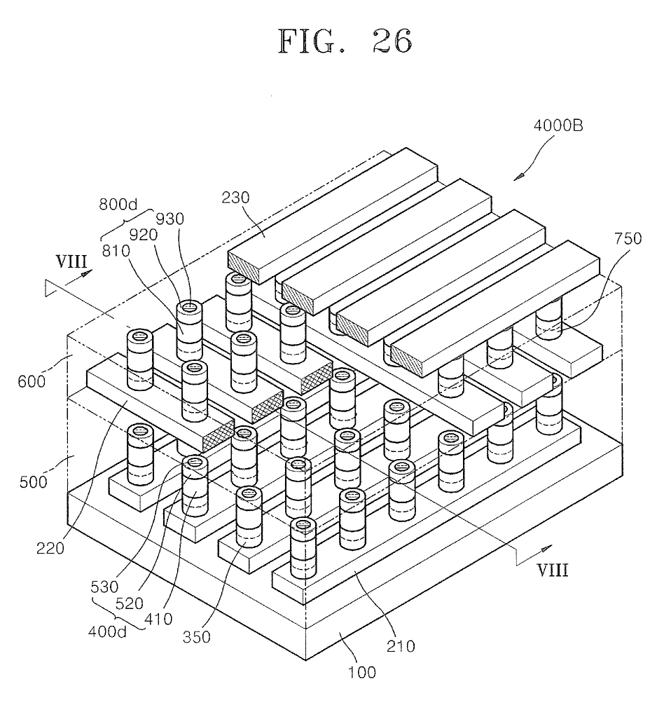

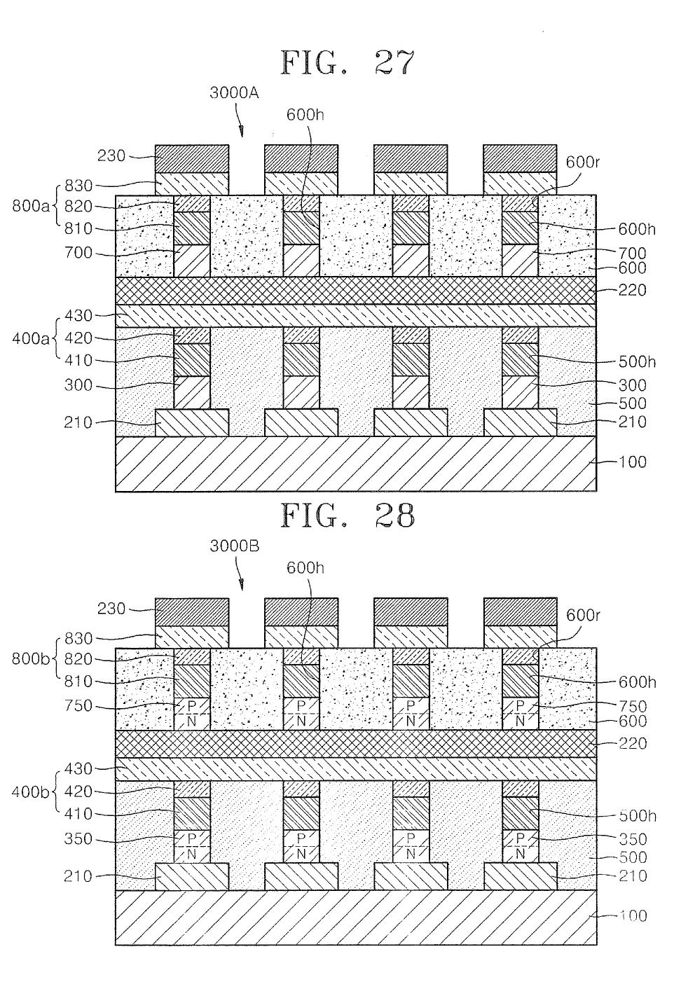

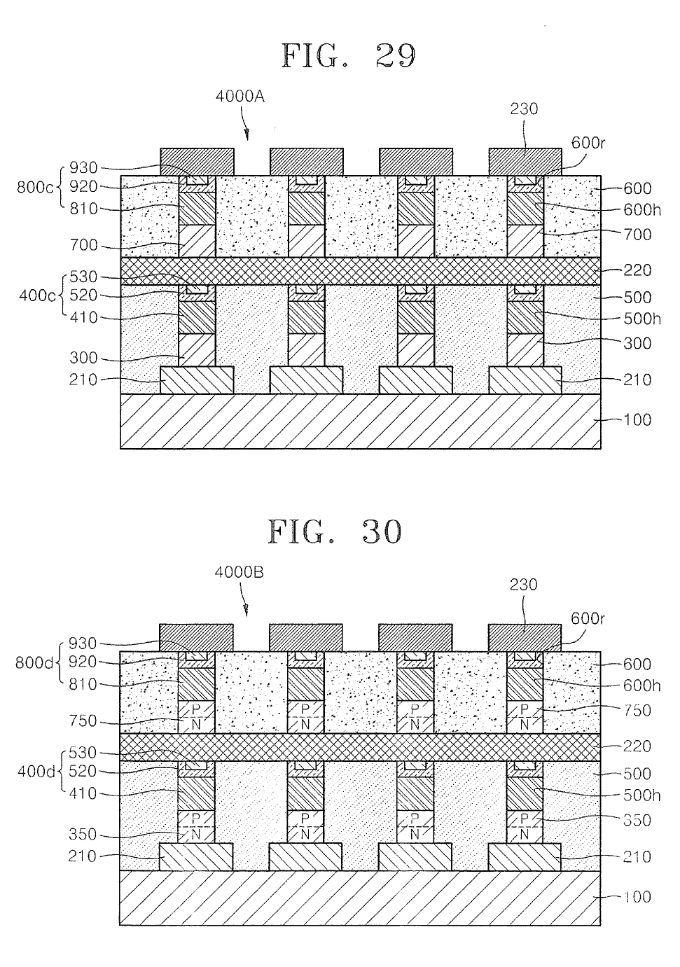

FIGS. 23-26 are perspective views illustrating laminated semiconductor memory devices 3000A, 3000B, 4000A and 4000B having resistive memory cell structures according to additional embodiments of the present invention. FIGS. 27-30 are cross-sectional views of FIGS. 23-26 along lines V-V, VI-VI, VII-VII, and VIII, respectively.

Referring to FIGS. 23-26, semiconductor memory devices 3000A, 3000B, 4000A and 4000B include a lower memory cell arrays corresponding to those described above with reference to FIGS. 3-6, with like components indicated by like reference numerals. Further description of these structures and operations for fabrication thereof will not be provided in light of the foregoing description.

As further illustrated, upper memory cell arrays similar to the lower memory cell arrays may be stacked on the lower structures. In FIGS. 23-26, upper memory cell arrays of the devices 3000A, 3000B, 4000A and 4000B include an interlayer insulating layer 600 with memory cell structures 800a, 800b, 800c or 800d formed therein, each memory cell structure 800a, 800b, 800c or 800d including a conductive plug 700 or diode 750 in a hole in the interlayer insulating layer 600, a bottom electrode 810 on the conductive plug 700 or diode 750, a resistive memory material region 820 or 920 on the bottom electrode 810, and an upper electrode 830 or 930 on the resistive memory material region 820 or 920. A conductive line 230 (e.g. a word line) is formed on the upper electrode 830 or 930. In some embodiments of the present invention, the conductive lines 220 may be bit lines for both the lower memory cell array and the memory cell array. Thus, a laminated semiconductor memory device capable of achieving high memory cell density may be provided.

The upper memory cell arrays may be manufactured using similar operations to those described above with reference to FIGS. 7-22. For example, referring to FIGS. 27-30, after the conductive line 220 is formed, the interlayer insulating layer 600 may be formed on the conductive line 220. A hole 600h may be formed in the interlayer insulating layer 600 to expose an upper surface of the conductive line 220. A conductive plug 700 or diode 750 may be formed in the hole 600h, and a bottom electrode 810 is formed on the conductive plug 700 or diode 750, leaving a recess 600r. A resistive memory material region 820 or 920 is formed in the recess 600r and a top electrode 830 or 930 is formed on the resistive memory material region 820 or 920. A conductive line 230 is formed on the top electrode 830 or 930.

In the illustrated embodiments, the conductive lines 210, 220 and 230 are shown as generally orthogonal, but it will be understood that the invention is not limited to such a configuration. For example, in some embodiments, the conductive lines 210, 220 and 230 may cross diagonally or in some other non-orthogonal manner. The present invention provides resistive memory cells that include respective discrete resistive memory material regions disposed in respective holes in an interlayer insulating layer, as opposed to memory cells that have resistive memory material layers that extend across the interlayer insulating layer and may be vulnerable to silicide-related lift off as described above. Although the above-described embodiments illustrate memory cells with resistive memory material regions that are substantially contained within a hole through an interlayer insulating layer, which may minimize the likelihood of such liftoff, it will be appreciated that, in other embodiments of the present invention, substantially similar benefits may be obtained with discrete resistive memory material regions that are not fully contained within a hole.

According to the present invention, since the first resistive memory material region is patterned by planarization, conventional damage on sidewalls of a resistive memory material region may be reduced. Thus, a memory device having a resistive structure with higher reliability may be provided.

In some embodiments of the present invention, a semiconductor memory device may have a reduced interface surface between a resistive memory material region and an interlayer insulating layer by containing the resistive memory material in a hole in the interlayer insulating layer, which may reduce or prevent formation of a silicide layer generated on the interface between the resistive memory material and the interlayer insulating layer. In addition, current needed for programming may be reduced by reducing the surface area of a programming region of a cell. This may allow reduction in the size of a transistor to supply the programming current, which may be advantageous for increasing integration.

According to some embodiments of the present invention, a size of the programming region and a crystal grain of the resistive memory material may be substantially the same, which may reduce leakage current through the grain. In addition, because a two-component metal oxide resistive memory material used for the memory cell and having a low heat transmission coefficient is contained within a relatively small region, heat transmission efficiency may be improved.

In some embodiments, a resistive memory material region is formed locally in a hole, the surface area of the interface between the resistive memory material region and the interlayer insulating layer may be reduced, and formation of a silicide layer generated on the interface may be prevented. Accordingly, more reliable memory devices may be provided, as formation of a silicide layer may be reduced or prevented, even if a high temperature process is performed to form a diode and/or a resistive memory material region. In some embodiments, a resistive memory material region may be formed by planarization, which may reduce or prevent damage to sidewalls of the resistive memory material region caused by a conventional plasma etching processes. This may further improve reliability.

Some embodiments of the present invention provide a semiconductor memory device in which formation of silicide by a reaction between a resistive memory material region and an interlayer insulating layer may be reduced or eliminated.

According to some embodiments, a semiconductor memory device in includes: a first conductive line on a semiconductor substrate; a first interlayer insulating layer comprising a first via hole exposing an upper surface of the first conductive line; a first bottom electrode electrically connected to the first conductive line, the first bottom electrode defining a first recess region in the first via hole; a first resistive memory material region formed locally in the first recess region; a first top electrode formed on the first resistive memory material region; and a second conductive line electrically connected to the first top electrode.

The semiconductor memory device may further include a first conductive plug and/or a first diode between the upper surface of the first conductive line and the first bottom electrode.

The first resistive memory material region may have an upper surface at the same level as the upper surface of the first interlayer insulating layer.

The first resistive memory material region may be formed to a predetermined thickness on the bottom and sidewalls of the first recess region to define a first groove.

The first top electrode may be buried in the first groove.

The first conductive line and the second conductive line may cross each other at a predetermined angle.

The first conductive line may be a word line and the second conductive line may be a bit line.

The semiconductor memory device may further include: a second interlayer insulating layer including a second via hole exposing an upper surface of the second conductive line; a second bottom electrode electrically connected to the first conductive line, the second bottom electrode defining a second recess region in the second via hole; a second resistive memory material region locally formed in the second recess region; a second top electrode formed on the second resistive memory material region; and a third conductive line electrically connected to the second top electrode.

The semiconductor memory device may further include: a second conductive plug and/or a second diode between the upper surface of the second conductive line and the second bottom electrode.

The third conductive line and the second conductive line may cross each other at a predetermined angle.

The third conductive line may be a word line and the second conductive line may be shared as a bit line.

The first conductive line and/or the second conductive line may be formed from tungsten or tungsten compound.

At least one of the first conductive line, the second conductive line and the third conductive line may be formed from tungsten or tungsten compound.

The first conductive plug and/or the second conductive plug may be formed from a polysilicon.

The first diode and/or the second diode may be formed from a polysilicon doped with impurities.

The first resistive memory material region and/or the second resistive memory material region may be formed from at least an oxide of a material selected from the group consisting of Ni, Nb, Ti, Zr, Hf, Co, Fe, Cu, Al, and Cu or a combination of these oxides.

The first top electrode and/or the second top electrode may be formed from at least one of iridium (Ir), platinum (Pt), and ruthenium (Ru), or a combination of these materials.

The first bottom electrode and/or the second bottom electrode may be formed from at least one of polysilicon, tungsten (W), titanium nitride (TiN), and titanium aluminum nitride (TiAlN) or a combination of theses materials.

According to further embodiments, methods of fabricating semiconductor memory devices include: providing a semiconductor substrate on which a first conductive line is formed; forming a first interlayer insulating layer on the first conductive line; forming a first via hole exposing an upper surface of the first conductive line in the first interlayer insulating layer; forming a first bottom electrode layer to bury the first via hole on the second interlayer insulating layer; forming a first bottom electrode defining a first recess region in the first via hole by recessing the first bottom electrode layer to a predetermined depth; forming a first resistive memory material region locally in the first recess region; forming a first top electrode on the first resistive memory material region; and forming a second conductive line electrically connected to the first top electrode.

The methods may further include, prior to the forming of a first bottom electrode layer, forming a first conductive plug or a first diode between the upper surface of the first conductive line and the first bottom electrode.

The forming of the first conductive plug may include: depositing a first conductive material layer on the first insulating layer to bury the first via hole; planarizing the first conductive material layer to expose an upper surface of the first interlayer insulating layer; and recessing the first conductive plug by etching the planarized first conductive material layer.

The forming of the first diode may include: depositing a first conductive material layer on the first interlayer insulating layer to bury the first via hole; planarizing the first conductive material layer to expose an upper surface of the first interlayer insulating layer; recessing the planarized first conductive material layer by etching; and forming a p-n junction to the recessed first conductive material layer by impurity ion injection.

The forming of the first bottom electrode may include: depositing the first bottom electrode layer on the first interlayer insulating layer to bury the first via hole; planarizing the first bottom electrode layer to expose an upper surface of the first interlayer insulating layer; and defining the first recess region by etching the planarized first bottom electrode layer.

The forming a first resistive memory material region locally may include: depositing the first resistive memory material region on the first interlayer insulating layer to bury the first recess region; and planarizing the first resistive memory material region to expose an upper surface of the first interlayer insulating layer.

The second conductive line and the first top electrode may be patterned at the same time.

The forming a first resistive memory material region locally may include: defining a first groove by depositing a first resistive memory material region having a predetermined thickness on the first recess region and the first interlayer insulating layer; and wherein the forming of a first top electrode includes: depositing the first top electrode layer on the first resistive memory material region to bury the first groove; and planarizing the first top electrode layer and the first resistive memory material region continuously until the upper surface of the interlayer insulating layer is exposed.

The method may further include after the forming of the second conductive line: forming a second interlayer insulating layer on the second conductive line; forming a second via hole in the second interlayer insulating layers the second via hole exposing the upper surface of the second conductive line; forming a second bottom electrode layer to bury the second via hole on the second interlayer insulating layer; forming a second bottom electrode defining a second recess region in the first via hole by recessing the second bottom electrode layer to a predetermined depth; forming a second resistive memory material region in the second recess region locally; forming a second top electrode on the second resistive memory material region; and forming a third conductive line in lines that is connected to the second top electrode.

The method may further include, prior to the forming of a second bottom electrode layer, forming a second conductive plug or a second diode burying a portion of the bottom of the second via hole.

The first and/or second resistive memory material regions may be formed from an oxide of one of Ni, Nb, Ti, Zr, Hf, Co, Fe, Cu, Al, and Cu, or a combination thereof.

The first and/or second electrodes may be formed of at least one of iridium (Ir), platinum (Pt), and ruthenium (Ru), or a combination thereof.

The first and/or second bottom electrodes may be formed from at least one of polysilicon, tungsten (W), titanium nitride layer (TiN), and titanium aluminum nitride (TiAlN) layer or a combination thereof.

The foregoing is illustrative of the present invention and is not to be construed as limiting thereof. Although a few embodiments of this invention have been described, those skilled in the art will readily appreciate that many modifications are possible in the embodiments without materially departing from the novel teachings and advantages of this invention. Accordingly, all such modifications are intended to be included within the scope of this invention as defined in the claims. The invention is defined by the following claims.

What is claimed is:

1. A semiconductor memory device comprising:
a first conductive line on a semiconductor substrate;
an interlayer insulating layer on the first conductive line;
a second conductive line on the interlayer insulating layer; and
a memory cell at an intersection of the first and second conductive lines, the memory cell comprising a discrete resistive memory material region disposed in a hole through the interlayer insulating layer and electrically connected between the first and second conductive lines.

2. The semiconductor memory device of claim 1, wherein the resistive memory material region is substantially contained within the hole.

3. The semiconductor memory device of claim 1, wherein contact between the resistive memory material region and the interlayer insulating layer is substantially limited to sidewalls of the interlayer insulating layer in the hole.

4. The semiconductor memory device of claim 1, wherein the memory cell further comprises a conductive region and/or a diode in the hole and electrically connected between the resistive memory material region and the first conductive line.

5. The semi conductor memory device of claim 1, further comprising an electrode on the interlayer insulating layer and connecting the resistive memory material region to the second conductive line.

6. The semiconductor memory device of claim 1, wherein the memory cell further comprises an electrode disposed in a recess defined by the resistive memory material region and in contact with the second conductive line.

7. The semiconductor memory device of claim 1, wherein the first conductive line is a word line and the second conductive line is a bit line.

8. The semiconductor memory device of claim 1, wherein the interlayer insulating layer comprises a first interlayer insulating layer, wherein the memory cell is a first memory cell, and wherein the semiconductor memory device further comprises:
a second interlayer insulating layer on the second conductive line;
a third conductive line on the second interlayer insulating layer; and
a second memory cell at an intersection of the second and third conductive lines, the second memory cell comprising a discrete resistive memory material region disposed in a hole through the second interlayer insulating layer and electrically connected between the second and third conductive lines.

9. The semiconductor memory device of claim 8, wherein the resistive memory material region of the second memory cell is substantially contained within the hole through the second interlayer insulating layer.

10. The semiconductor memory device of claim 8, wherein contact between the resistive memory material region of the second memory cell and the second interlayer insulating layer is substantially confined to sidewalls of the hole through the second interlayer insulating layer.

11. The semiconductor memory device of claim 8, wherein the second memory cell further comprises a conductive region and/or a diode in the hole through the second interlayer insulating layer and electrically connected between the resistive memory material region of the second memory cell and the second conductive line.

12. The semiconductor memory device of claim 8, further comprising an electrode on the second interlayer insulating layer and connecting the resistive memory material region of the second memory cell to the third conductive line.

13. The semiconductor memory device of claim 8, wherein the second memory cell further comprises an electrode disposed in a recess defined by the resistive memory material region of the second memory cell and in contact with the third conductive line.

14. The semiconductor memory device of claim 8, wherein the first and third conductive lines are word lines and the second conductive line is a bit line.

15. A method of fabricating a semiconductor memory device, the method comprising:
forming a first conductive line on a substrate;
forming an interlayer insulating layer on the conductive line;
removing a portion of the interlayer insulating layer to form a hole that exposes the first conductive line;
forming a memory cell on the exposed first conductive line, the memory cell including a discrete resistive memory material region in the hole and in contact with first conductive line; and
forming a second conductive line on the interlayer insulating layer and the memory cell, the second conductive line electrically connected to the resistive memory material region.

16. The method of claim 15, wherein the resistive memory material region is substantially contained within the hole.

17. The method of claim 1, wherein contact between the resistive memory material region and the interlayer insulating layer is substantially limited to sidewalls of the interlayer insulating layer in the hole.

18. The method of claim 15, wherein forming a memory cell comprises:
forming a first conductive material layer on the interlayer insulating layer and in the hole;
planarizing the first conductive material layer to expose the interlayer insulating layer and leave a portion of the first conductive material layer in the hole;
etching a portion of the conductive material layer remaining in the hole to form a recessed conductive plug in the hole; and
forming the resistive memory material region on the conductive plug.

19. The method of claim 18, wherein forming a memory cell further comprises:
forming a second conductive layer on the first interlayer insulating layer and on the conductive plug in the hole;
planarizing the second conductive layer to expose the interlayer insulating layer and leave a portion of the second conductive layer in the hole; and
etching a portion of the second conductive layer remaining in the hole to leave a recessed electrode on the conductive plug; and
forming the resistive memory material region on the electrode.

20. The method of claim 15, wherein forming a memory cell comprises:
forming a semiconductor material layer on the interlayer insulating layer and in the hole;
planarizing the semiconductor material layer to expose the interlayer insulating layer and leave a portion of the semiconductor material layer in the hole;
etching a portion of the semiconductor material remaining in the hole to form a recessed semiconductor region in the hole;
implanting impurities into the semiconductor region to form a diode; and
forming the resistive memory material region on the diode.

21. The method of claim 20, wherein forming a memory cell further comprises:
forming a conductive layer on the first interlayer insulating layer and on the diode in the hole;
planarizing the conductive layer to expose the interlayer insulating layer and leave a portion of the conductive layer in the hole; and
etching a portion of the conductive layer remaining in the hole to leave a recessed electrode on the diode; and
forming the resistive memory material region on the electrode.

22. The method of claim 15, wherein forming a memory cell comprises:
forming an electrode in the hole in electrical contact with the first conductive line;
forming a resistive memory material layer on the interlayer insulating layer and on the electrode in the hole; and
planarizing the resistive memory material layer to expose the interlayer insulating layer and leave the resistive memory material region on the electrode in the hole.

23. The method of claim 22:
wherein forming an electrode comprises forming a first electrode;
wherein forming a resistive memory material layer on the interlayer insulating layer and on the electrode in the hole comprises forming the resistive memory material layer on the first electrode to a thickness sufficient to fully fill the hole; and
wherein planarizing the resistive memory material layer to expose the interlayer insulating layer and leave the resistive memory material region on the electrode in the hole comprises planarizing the resistive memory material layer such that the resistive memory material region on the electrode in the hole is substantially flush with the exposed interlayer insulating layer;
wherein forming a memory cell further comprises forming a second electrode on the interlayer insulating layer and the resistive memory material region; and
wherein forming a second conductive line comprises forming the second conductive line on the second electrode.

24. The method of claim 22:
wherein forming an electrode comprises forming a first electrode;
wherein forming a resistive memory material layer on the interlayer insulating layer and on the electrode in the hole comprises forming the resistive memory material layer to a thickness sufficient to cover a bottom and sidewall of the hole and define a recess bounded by the resistive memory material layer;
wherein planarizing the resistive memory material layer to expose the interlayer insulating layer and leave the resistive memory material region on the electrode in the hole is preceded by forming a conductive material layer on the resistive memory material layer and comprises planarizing the conductive material layer to form a second electrode in the recess in the resistive memory material region; and
wherein forming a second conductive line comprises forming the second conductive line on the second electrode.

25. The method of claim 15, wherein the interlayer insulating layer comprises a first interlayer insulating layer, wherein the memory cell comprises a first memory cell, and wherein the method further comprises:
forming a second interlayer insulating layer on the second conductive line;
removing a portion of the second interlayer insulating layer to form a hole through the second interlayer insulating layer that exposes the second conductive line;
forming a second memory cell on the exposed second conductive line, the second memory cell including a resistive memory material region in the hole through the second interlayer insulating layer and in contact with the second conductive line; and
forming a third conductive line on the second interlayer insulating layer and the second memory cell, the third conductive line electrically connected to the resistive memory material region of the second memory cell.
